(19) United States
(12) Patent Application Publication
(10) Pub. No.: US 2014/0159829 A1
(43) Pub. Date: Jun. 12, 2014

(54) VARIABLE CAPACITANCE CIRCUIT

(71) Applicant: SAMSUNG ELECTRO-MECHANICS CO., LTD., Suwon (KR)

(72) Inventors: Jae Hyouck CHOI, Suwon (KR); Sung Hwan PARK, Suwon (KR); Jeong Hoon KIM, Suwon (KR); Chan Yong JEONG, Suwon (KR); Sang Wook PARK, Suwon (KR)

(73) Assignee: SAMSUNG ELECTRO-MECHANICS CO., LTD., Suwon (KR)

(21) Appl. No.: 13/779,649

(22) Filed: Feb. 27, 2013

(30) Foreign Application Priority Data
Dec. 10, 2012 (KR) 10-2012-0142919

(51) Int. Cl. H03H 7/38

(52) U.S. Cl. CPC H03H 7/38
USPC 333/32

(57) ABSTRACT

There is provided a variable capacitance circuit, including a capacitance circuit unit connected between a first terminal and a second terminal and providing a preset capacitance, a variable capacitance circuit unit including a first transistor connected to the capacitance circuit unit in series between the first terminal and the second terminal, the first transistor being operated according to a gate voltage, and a switching unit connected between a body of the first transistor and an input terminal of a preset body voltage, wherein the switching unit is turned off when the first transistor is turned on and turned on when the first transistor is turned off.

### CROSS-REFERENCE TO RELATED APPLICATIONS

This application claims the priority of Korean Patent Application No. 10-2012-0142919 filed on Dec. 10, 2012, in the Korean Intellectual Property Office, the disclosure of which is incorporated herein by reference.

### BACKGROUND OF THE INVENTION

1. Field of the Invention

The present invention relates to a variable capacitance circuit that can be applied to a tunable matching network (TMN), and the like, such as a front-end module.

2. Description of the Related Art

Generally, with the development of wireless communications technologies, 4G mobile communications, represented by long term evolution (LTE), in addition to 3G mobile communications, have been implemented. In accordance with the addition of 4G mobile communications network functions to existing 3G mobile communications networks, many methods for supporting a single mobile phone have been required.

To this end, matters required for RF performance are as follows. First, there is a need to cover various frequency bands with a single RF chain, second, there is a need to optimize power consumed by a power amplifier (PA) by optimizing front-end matching in addition to an antenna during the use of a mobile phone, third, there is a need to optimize a reception rate of a low noise amplifier (LNA) by optimizing front-end matching in addition to an antenna during the use of a mobile phone, and the like.

In order to implement the foregoing functions, there is a need to secure flexibility by adding a tunable matching network to an existing RF front-end having a fixed structure. Herein, a variable element is used for tunable performance. In this case, a variable capacitor element may be used.

Meanwhile, in order to increase the tuning range of the system, there is a need to increase a range between maximum capacitance Cmax and minimum capacitance Cmin that determine the tuning range of the variable capacitor and in order to secure system stability, there is a need for excellent linearity in a variable capacitor. Further, in order to reduce system loss, there is a need to increase a Q value (=X/R, where X is reactance and R is resistance) of the variable capacitor.

The existing variable capacitance method is implemented by a circuit configured of a combination of a main capacitor and a variable capacitance element. In this case, as the variable capacitance element, a floating body transistor is used.

The floating body transistor is turned on when a gate voltage is at a high level. In this case, since there are no capacitors connected to the main capacitor, the floating body transistor becomes the maximum capacitance Cmax.

Differently from this, as the floating body transistor acts as the capacitance element in which the floating body transistor is connected to the main capacitor in series when the gate voltage is in a low level, the floating body transistor becomes the minimum capacitance Cmin.

As described above, the existing variable capacitance method may use the floating body transistor. In this case, on resistance may be relatively low in the state in which the floating body transistor is in a turned-on state, but linearity may be deteriorated when the floating body transistor is in a turned-off state.

The following Related Art Document according to the related art relates to a matching circuit between digital tuning possible stages and does not disclose technical matters using a floating body transistor and a contact body transistor.

### RELATED ART DOCUMENT

Korean Patent Laid-Open Publication No. 2012-0049341

### SUMMARY OF THE INVENTION

An aspect of the present invention provides a variable capacitance circuit capable of selecting a floating body mode or a contact body mode.

According to an aspect of the present invention, there is provided a variable capacitance circuit, including: a capacitance circuit unit connected between a first terminal and a second terminal and providing capacitance; a variable capacitance circuit unit including a first transistor connected to the capacitance circuit unit in series between the first terminal and the second terminal, the first transistor being operated according to a gate voltage; and a switching unit connected between a body of the first transistor and an input terminal of a preset body voltage, wherein the switching unit is turned off when the first transistor is turned on and turned on when the first transistor is turned off.

The switching unit may be configured of a switching transistor connected between a common node connected to the respective bodies of the first through n-th transistors and the input terminal of the body voltage and is turned off when the first to n-th transistors are turned on and turned on when the first through n-th transistors are turned off, according to preset switching voltage.

According to another aspect of the present invention, there is provided a variable capacitance circuit, including: a capacitance circuit unit connected between a first terminal and a second terminal and providing a preset capacitance; a variable capacitance circuit unit including a first transistor connected to the capacitance circuit unit in series between the first terminal and the second terminal, the first transistor being operated according to a gate voltage; a switching unit connected between a body of the first transistor and an input terminal of preset body voltage; and a control unit turning the first transistor on and turning the switching unit off in a preset floating body mode and turning the first transistor off and turning the switching unit on in a preset contact body mode.

The capacitance circuit unit may include at least one capacitance element and the at least one capacitance element may be one of a metal oxide semiconductor (MOS) capacitor and a metal-insulator-metal (MIM) capacitor.

The variable capacitance circuit unit may include: a transistor circuit unit including the first transistor and second through n-th transistors connected to the first transistor in series, the first through n-th transistors being operated according to the gate voltage; a gate resistor unit including first through n-th gate resistors connected between respective gates of the first through n-th transistors and an input terminal of the gate voltage; and a body resistor unit including first through n-th body resistors connected between respective bodies of the first through n-th transistors and an input terminal of the body voltage.

In the transistor circuit unit, the amount of transistors connected in series may be determined according to a power differential between the first terminal and the second terminal.

The first through n-th transistors may be configured of one of a metal oxide semiconductor field-effect transistor (MOSFET) and a metal semiconductor field effect transistor (MESFET).

The switching unit may be configured of a switching transistor connected between a common node connected to the respective bodies of the first through n-th transistors and the input terminal of the body voltage and is turned off when the first to n-th transistors are turned on and turned on when the first through n-th transistors are turned off, according to a control from the control unit.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a block diagram of a variable capacitance circuit according to an embodiment of the present invention;

FIG. 2 illustrates a modified example of the variable capacitance circuit according to an embodiment of the present invention;

FIG. 3 is a block diagram of a variable capacitance circuit according to another embodiment of the present invention;

FIG. 4 illustrates a modified example of the variable capacitance circuit according to another embodiment of the present invention;

FIG. 5 is a first equivalent circuit diagram of the variable capacitance circuit according to the embodiment of the present invention;

FIG. 6 is a second equivalent circuit diagram of the variable capacitance circuit according to the embodiment of the present invention;

FIG. 7 is a graph illustrating characteristics of body voltage-capacitance according to the embodiment of the present invention; and

FIG. 8 is a graph illustrating characteristics of gate voltage-capacitance according to the embodiment of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In addition, in each embodiment of the present invention, since a structure, a shape, a numerical value described by way of example are only examples provided in order to assist in the understanding of technical features of the present invention, they are not limited to these examples, but may be variously changed within the spirit and the scope of the present invention.

Further, throughout the drawings accompanying the present invention, components having substantially the same configuration and functions will be denoted by the same reference numerals.

Hereinafter, embodiments of the present invention will be described in detail with reference to the accompanying drawings so that those skilled in the art may easily practice the present invention.

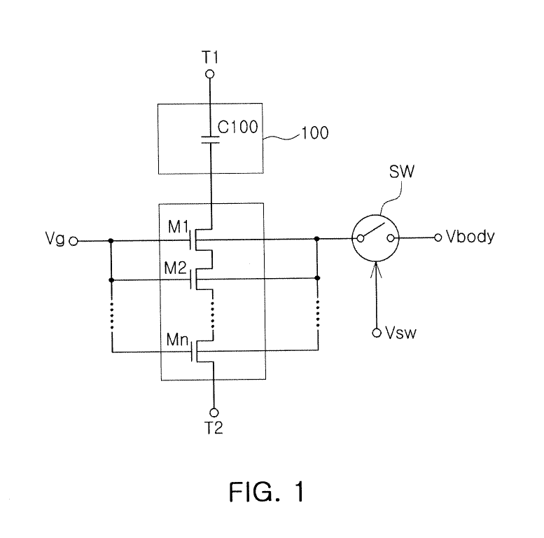

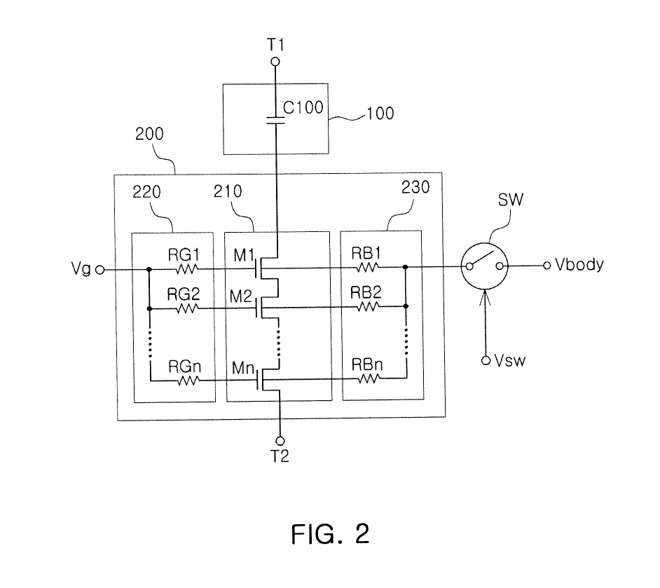

FIG. 1 is a block diagram of a variable capacitance circuit according to an embodiment of the present invention, while FIG. 2 illustrates a modified example of the variable capacitance circuit according to an embodiment of the present invention.

Referring to FIGS. 1 and 2, the variable capacitance circuit according to an embodiment of the present invention may include a capacitance circuit unit 100, a variable capacitance circuit unit 200, and a switching unit SW.

The capacitance circuit unit 100 is connected between a first terminal T1 and a second terminal T2 and may provide preset capacitance C100.

In this case, the capacitance circuit unit 100 may include at least one capacitance element. In this case, the capacitance element may be a fixed capacitance element or a variable capacitance element. Further, the capacitance circuit unit 100 may be configured of a combination of a fixed capacitance element and a variable capacitance element.

For example, when the capacitance element is a fixed capacitance element, the capacitance element may be one of a metal-oxide semiconductor (MOS) capacitor and a metal-insulator-metal (MIM) capacitor.

The variable capacitance circuit unit 200 includes a first transistor M1 connected to the capacitance circuit unit 100 in series between the first terminal T1 and the second terminal T2 and the first transistor M1 may be operated according to a gate voltage Vg.

That is, the variable capacitance circuit unit 200 may include the first transistor M1 and further include second through n-th transistors M2 through Mn connected to the first transistor M1 in series.

In this case, the first through n-th transistors M1 through Mn may be operated according to the gate voltage Vg.

In a floating body mode, the switching unit SW may be connected between a body of the first transistor M1 and an input terminal of a preset body voltage Vbody according to a switching voltage Vsw. In this configuration, the floating body mode indicates that the body is in a floating state without voltage being applied to respective bodies of the first through n-th transistors M1 through Mn of the variable capacitance circuit unit 200.

In this case, in a contact body mode, the switching unit SW may be turned off when the first transistor M1 is turned on, and may be turned on when the first transistor M1 is turned off, according to the switching voltage Vsw. Here, the contact body mode indicates the state in which the input terminal of the body voltage Vbody contacts the respective bodies of the first through n-th transistors M1 through Mn of the variable capacitance circuit unit 200. In this case, the body voltage Vbody is applied to the body.

Referring to FIG. 2, the variable capacitance circuit unit 200 may include a transistor circuit unit 210, a gate resistor unit 220, and a body resistor unit 230.

The transistor circuit unit 210 may include a single first transistor M1 or may further include a plurality of first through n-th transistors M1 through Mn.

Here, the first through n-th transistors M1 through Mn may be configured of at least one of a metal oxide semiconductor field-effect transistor (MOSFET) and a metal semiconductor field effect transistor (MOSFET).

In this case, in the transistor circuit unit 210, the amount of transistors connected in series may be determined according to a power differential between the first terminal T1 and the second terminal T2.

For example, when power of 3W is applied between the first terminal T1 and the second terminal T2 and one of the used transistors may withstand 0.3 W, the transistor circuit unit 210 may include at least ten transistors that are connected to each other in series.

The gate resistor unit 220 may include first through n-th gate resistors RG1 through RGn that are connected between respective gates of the first through n-th transistors M1 through Mn and the input terminal of the gate voltage Vg. In this case, the respective first through n-th gate resistors RG1 through RGn are bias resistors of the respective gates of the first through n-th transistors M1 through Mn.

The body resistor unit 230 may include first through n-th body resistors RB1 through RBn that are connected between respective bodies of the first through n-th transistors M1 through Mn and the input terminal of the body voltage Vbody. In this case, the respective first through n-th body resistors RB1 through RBn are bias resistors of the respective bodies of the first through n-th transistors M1 through Mn.

The switching unit SW may be configured of a switching transistor. In this case, the switching transistor may be connected between a common node connected to the respective bodies of the first through n-th transistors M1 through Mn and the input terminal of the body voltage Vbody.

Further, in the floating body mode, the switching transistor may be turned off when the first through n-th transistors M1 through Mn are turned on according to the switching voltage Vsw. In the contact body mode, the switching transistor may be turned on when the first through n-th transistors M1 through Mn are turned off according to the switching voltage Vsw.

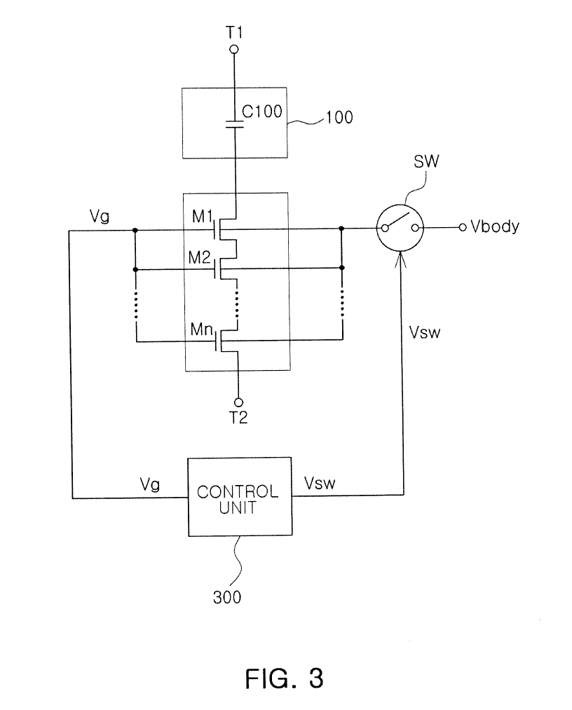

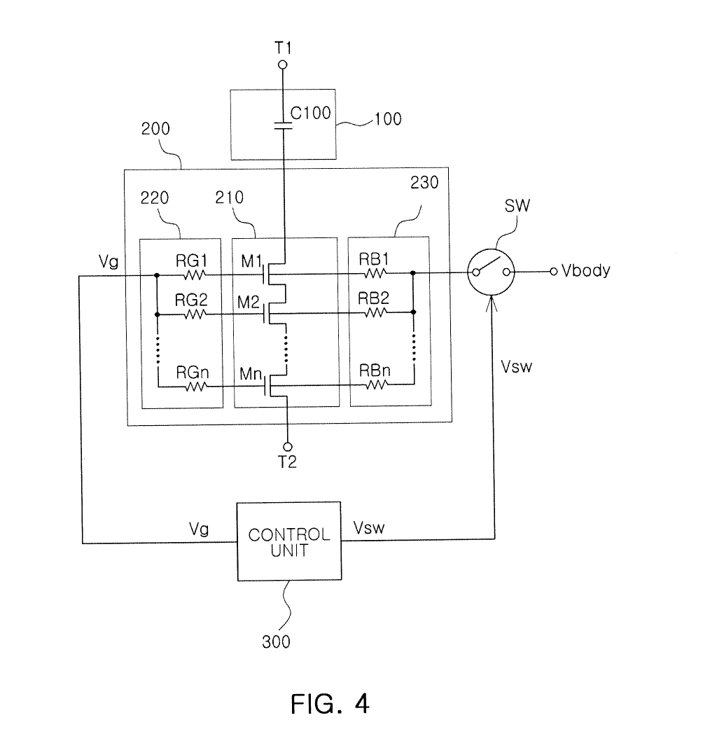

FIG. 3 is a block diagram of a variable capacitance circuit according to another embodiment of the present invention. FIG. 4 illustrates a modified example of the variable capacitance circuit according to another embodiment of the present invention.

Referring to FIGS. 3 and 4, the variable capacitance circuit according to another embodiment of the present invention may include a capacitance circuit unit 100, a variable capacitance circuit unit 200, a switching unit SW, and a control unit 300.

As described above, the variable capacitance circuit according to another embodiment of the present invention further includes the control unit 300 in addition to the components of the variable capacitance circuit of the foregoing embodiment of the present invention, and therefore overlapping descriptions will be omitted. Accordingly, the control unit 300 will be described below.

In the preset floating body mode, the control unit 300 may perform a control such that the first through n-th transistors M1 through Mn are turned on and the switching unit SW is turned off.

Therefore, the switching unit SW may be configured of a switching transistor. The switching unit SW may be turned off when the first through n-th transistors M1 through Mn are turned on according to the control from the control unit 300.

Further, in the preset contact body mode, the control unit 300 may turn the first through n-th transistors M1 through Mn off and turn the switching unit SW on.

Therefore, the switching unit SW may be turned on when the first through n-th transistors M1 through Mn are turned off.

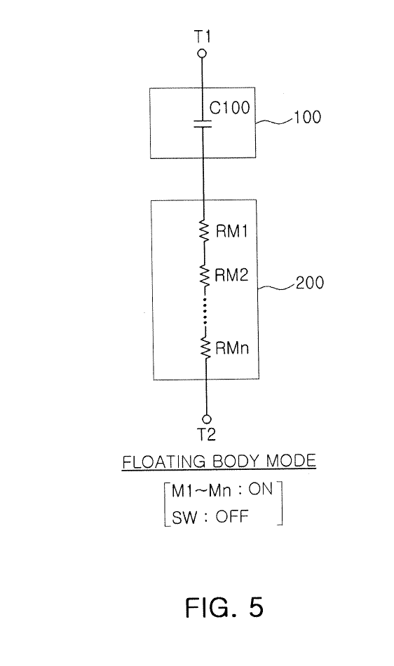

FIG. 5 is a first equivalent circuit diagram of the variable capacitance circuit according to the embodiment of the present invention.

Referring to FIG. 5, when the first through n-th transistors M1 through Mn are turned on, the switching unit SW is turned off, such that the first through n-th transistors M1 through Mn are operated as the floating body transistor and the operating mode becomes the floating body mode.

In the floating body mode described above, the variable capacitance circuit unit 200 may be illustrated as in FIG. 5. the respective first through n-th transistors M1 through Mn may be schematically illustrated as first through n-th on resistances RM1 through RMn.

In the floating body mode, the first through n-th on resistances RM1 through RMn are relatively low, and thus the loss is reduced as much.

Further, as there is no capacitance provided from the variable capacitance circuit unit 200, the capacitance C100 provided from the capacitance circuit unit 100 becomes a maximum capacitance Cmax.

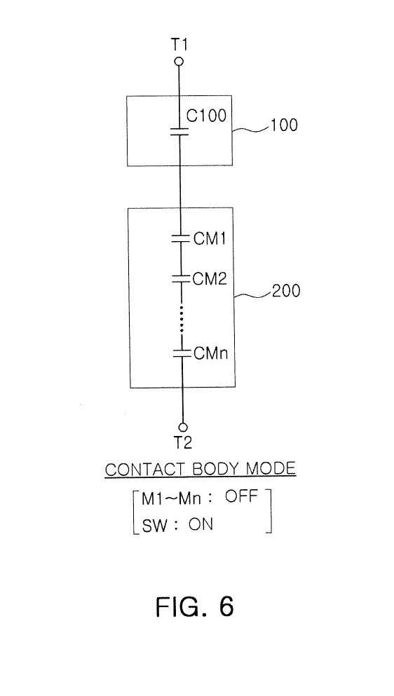

FIG. 6 is a second equivalent circuit diagram of the variable capacitance circuit according to the embodiment of the present invention.

Referring to FIG. 6, when the first through n-th transistors M1 through Mn are turned off, the switching unit SW is turned on, such that the first through n-th transistors M1 through Mn are operated as the contact body transistor. The operating mode becomes the contact body mode.

In the contact body mode, the variable capacitance circuit unit 200 may be schematically illustrated as in FIG. 6. the respective first through n-th transistors M1 through Mn may be schematically illustrated as first through n-th capacitors CM1 through CMn.

In the floating body mode, as the body voltage is applied to the bodies of the first through n-th transistors M1 through Mn, when the first through n-th transistors M1 through Mn are configured of MOSFET, the linearity in characteristics of the MOSFET may be improved.

Further, as the first through n-th capacitances CM1 through CMn are provided from the variable capacitance circuit unit 200, the first through n-th capacitances CM1 through CMn are a serial sum with the capacitance C100 provided from the capacitance circuit unit 100, and thus attain the minimum capacitance Cmin.

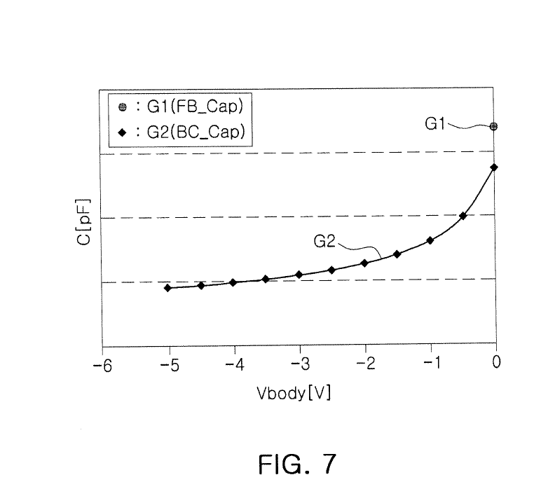

FIG. 7 is a graph illustrating characteristics of body voltage-capacitance according to the embodiment of the present invention.

In the graph illustrated in FIG. 7, G1 is capacitance FB-Cap of the first through n-th transistors M1 through Mn in the floating body mode and G2 is capacitance BC-Cap of the first through n-th transistors M1 through Mn in the contact body mode.

Referring to the graph of G1 and G2 illustrated in FIG. 7, the floating body transistor may control capacitance to be lowered according to the body voltage, as compared with the contact body transistor. Therefore, the linearity may be improved and the variable range may be expanded, due to the floating body transistor.

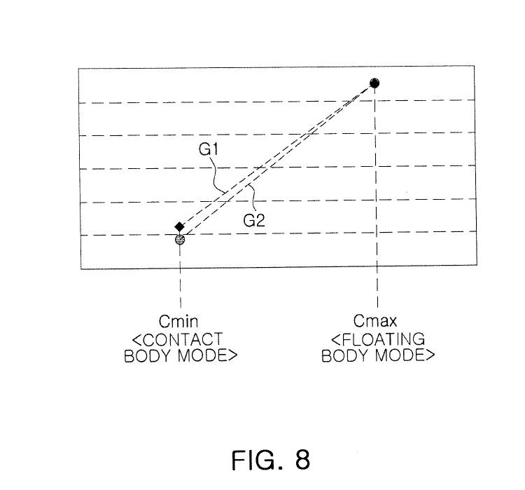

FIG. 8 is a graph illustrating characteristics of gate voltage-capacitance according to the embodiment of the present invention.

In the graph illustrated in FIG. 8, G1 refers to equivalent capacitance of the floating body transistor according to the related art and G2 refers to equivalent capacitance of the contact body transistor according to the embodiment of the present invention.

Referring to the graph of G1 and G2 illustrated in FIG. 8, according to the floating body transistor according to the related art, the capacitance is relatively large and the tuning range is relatively narrow when the floating body transistor according to the related art is turned off.

On the other hand, according to the embodiment of the present invention, as the transistor is operated as the contact body transistor when the transistor is turned off, the capacitance is relatively low.

Therefore, linearity may be improved and the variable range may be expanded, due to the floating body transistor.

As set forth above, according to the embodiments of the present invention, the excellent Q value may be maintained at a relatively maximum capacitance and the linearity may be improved at the relatively minimum capacitance, by selecting the floating body mode or the contact body mode. Further, according to the embodiments of the present invention, the tuning range may be extended by further reducing a relatively minimum capacitance, as compared with the related art.

While the present invention has been shown and described in connection with the embodiments, it will be apparent to those skilled in the art that modifications and variations may be made without departing from the spirit and scope of the invention as defined by the appended claims.

What is claimed is:

1. A variable capacitance circuit, comprising:
a capacitance circuit unit connected between a first terminal and a second terminal and providing capacitance;
a variable capacitance circuit unit including a first transistor connected to the capacitance circuit unit in series between the first terminal and the second terminal, the first transistor being operated according to a gate voltage; and
a switching unit connected between a body of the first transistor and an input terminal of a preset body voltage,
wherein the switching unit is turned off when the first transistor is turned on and turned on when the first transistor is turned off.

2. The variable capacitance circuit of claim 1, wherein the capacitance circuit unit includes:
at least one capacitance element, and
the at least one capacitance element is one of a metal oxide semiconductor (MOS) capacitor and a metal-insulator-metal (MIM) capacitor.

3. The variable capacitance circuit of claim 1, wherein the variable capacitance circuit unit includes:
a transistor circuit unit including the first transistor and second through n-th transistors connected to the first transistor in series, the first through n-th transistors being operated according to the gate voltage;
a gate resistor unit including first through n-th gate resistors connected between respective gates of the first through n-th transistors and an input terminal of the gate voltage; and
a body resistor unit including first through n-th body resistors connected between respective bodies of the first through n-th transistors and an input terminal of the body voltage.

4. The variable capacitance circuit of claim 3, wherein in the transistor circuit unit, the amount of transistors connected in series is determined according to a power differential between the first terminal and the second terminal.

5. The variable capacitance circuit of claim 3, wherein the first through n-th transistors are configured of one of a metal oxide semiconductor field-effect transistor (MOSFET) and a metal semiconductor field effect transistor (MESFET).

6. The variable capacitance circuit of claim 3, wherein the switching unit is configured of a switching transistor connected between a common node connected to the respective bodies of the first through n-th transistors and the input terminal of the body voltage, and is turned off when the first to n-th transistors are turned on and turned on when the first through n-th transistors are turned off, according to preset switching voltage.

7. A variable capacitance circuit, comprising:
a capacitance circuit unit connected between a first terminal and a second terminal and providing a preset capacitance;
a variable capacitance circuit unit including a first transistor connected to the capacitance circuit unit in series between the first terminal and the second terminal, the first transistor being operated according to a gate voltage;
a switching unit connected between a body of the first transistor and an input terminal of a preset body voltage; and
a control unit turning the first transistor on and turning the switching unit off in a preset floating body mode and turning the first transistor off and turning the switching unit on in a preset contact body mode.

8. The variable capacitance circuit of claim 7, wherein the capacitance circuit unit includes:
at least one capacitance element, and
the at least one capacitance element is one of a metal oxide semiconductor (MOS) capacitor and a metal-insulator-metal (MIM) capacitor.

9. The variable capacitance circuit of claim 7, wherein the variable capacitance circuit unit includes:
a transistor circuit unit including the first transistor and second through n-th transistors connected to the first transistor in series, the first through n-th transistors being operated according to the gate voltage;
a gate resistor unit including first through n-th gate resistors connected between respective gates of the first through n-th transistors and an input terminal of the gate voltage; and
a body resistor unit including first through n-th body resistors connected between respective bodies of the first through n-th transistors and an input terminal of the body voltage.

10. The variable capacitance circuit of claim 9, wherein in the transistor circuit unit, the amount of transistors connected in series is determined according to a power differential between the first terminal and the second terminal.

11. The variable capacitance circuit of claim 9, wherein the first through n-th transistors are configured of one of a metal oxide semiconductor field-effect transistor (MOSFET) and a metal semiconductor field effect transistor (MOSFET).

12. The variable capacitance circuit of claim 9, wherein the switching unit is configured of a switching transistor connected between a common node connected to the respective bodies of the first through n-th transistors and the input terminal of the body voltage and is turned off when the first to n-th transistors are turned on and turned on when the first through n-th transistors are turned off, according to a control from the control unit.
